(19) United States
(12) Patent Application Publication
(10) Pub. No.: US 2005/0230672 A1
(43) Pub. Date: Oct. 20, 2005

(54) III-V compound semiconductor crystals

(75) Inventors: Kaori Kurihara, Ushiku-shi (JP); Kenji Shimoyama, Ushiku-shi (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: MITSUBISHI CHEMICAL CORPORATION, Tokyo (JP)

(21) Appl. No.: 11/084,169

(22) Filed: Mar. 21, 2005

Related U.S. Application Data
(63) Continuation of application No. PCT/JP03/12007, filed on Sep. 19, 2003.

(30) Foreign Application Priority Data
Sep. 20, 2002 (JP) 2002-274905
Sep. 20, 2002 (JP) 2002-274906
Sep. 20, 2002 (JP) 2002-274907
May 8, 2003 (JP) 2003-130264
May 8, 2003 (JP) 2003-130265

(51) Int. Cl. H01L 29/06; H01L 21/00

(52) U.S. Cl. 257/11; 438/48

(57) ABSTRACT

III-V Compound semiconductor crystals characterized by containing Al and In as main constituent elements of group III, and also containing a constituent element of group V, and characterized in that the carbon concentration in the compound semiconductor crystals is 1×10¹⁶ cm⁻³ or higher, and the oxygen concentration therein is 1×10¹⁸ cm⁻³ or lower and is not higher than the carbon concentration; and a method for producing the III-V compound semiconductor crystals. By using the III-V compound semiconductor crystals, a semiconductor device showing satisfactory electric conductivity characteristics, and a semiconductor laser showing satisfactory high speed modulation characteristics can be provided.

The present application is a continuation of PCT/JP03/12007 filed on Sep. 19, 2003 and claims priority under 35 U.S.C. §119 of Japanese Patent Application No. 274905/2002 filed on Sep. 20, 2002, Japanese Patent Application No. 274906/2002 filed on Sep. 20, 2002, Japanese Patent Application No. 274907/2002 filed on Sep. 20, 2002, Japanese Patent Application No. 130264/2003 filed on May 8, 2003 and Japanese Patent Application No. 130265/2003 filed on May 8, 2003.

### BACKGROUND OF THE INVENTION

1. Field of the Invention

This invention relates to carbon-doped novel III-V compound semiconductor crystals, and a method for producing them. Using these III-V compound semiconductor crystals, a semiconductor device showing satisfactory electric conductivity characteristics, and a semiconductor laser showing satisfactory high speed modulation characteristics can be provided.

2. Description of the Related Art

In recent years, researches have become active on a semiconductor laser as a direct modulation light source for communications which utilizes an InAlGaAs-based material, instead of an InGaAsP-based material, formed on an InP substrate. The InAlGaAs-based material, compared with the InGaAsP-based material, is characterized in that it has a high differential gain, and has a large amount of band discontinuity of a conduction band. Thus, there are many reports that the InAlGaAs-based material is a material system suitable for a high temperature operating, high speed modulation laser. The InAlGaAs-based material has also attracted attention as a material system with high carrier mobility and a high peak carrier velocity.

FIG. 10 shows an InAlGaAs-based semiconductor laser structure as a conventional example, which is described in IEEE Journal on Selected Topics in Quantum Electronics, Vol. 7, No. 2 (2001), 340-349, in the form of a refractive index profile. This semiconductor laser has a structure in which an n type InP layer 11, an n type InAlGaAs compositionally graded layer 12, an n type InAlAs layer 13, a lower graded refractive index (GRIN) layer 14, an active layer 17 consisting of 5-period multiple quantum well layers 15 (AlGaInAs) and barrier layers 16 (InAlGaAs), an upper graded refractive index (GRIN) layer 18, a zinc-doped InAlAs layer 19, a zinc-doped InAlGaAs compositionally graded layer 20, a p type InP spacer layer 21, an InGaAsP etch stop layer 22, a p type InP outer cladding layer 23, and a p type InGaAs cap layer 24 are sequentially formed on an n type InP substrate 10 with the use of metal organic vapor phase epitaxy (MOVPE). As dopant materials, Si₂H₆ is usually used on the n-side, and DMZn on the p-side, as shown in IEEE Photonics Technology Letters, Vol. 11, No. 8 (1999), 949-951, but it is frequent practice to use H₂Se on the n-side, and DEZn on the p-side. Anyway, Zn is usually used as a dopant on the p-side.

A process as shown below is performed using such a stacked structure, whereby an InAlGaAs-based semiconductor laser as shown in FIG. 2 can be prepared. That is, a photoresist mask with stripes on the order of 5 μm in width and 300 μm in pitch is formed on the stacked structure. Wet etching is carried out with the use of this mask to form ridges 25. During the wet etching, an aqueous mixed solution of phosphoric acid and hydrogen peroxide is used on the p type InGaAs cap layer 24, and a diluted aqueous solution of hydrochloric acid is used on the p type InP outer cladding layer 23, whereby etching can be stopped at the InGaAsP etch stop layer 22 with good controllability. Then, the photoresist is stripped off, and an insulating film, such as a Si₃N₄ dielectric film 26, is formed on the entire surface. Further, contact holes 27 are selectively perforated in stripes on the top portions of mesas of the Si₃N₄ dielectric film 26, and a p type electrode 28 is formed. The substrate is polished to a thickness as thin as 100 μm, and an n type electrode 29 is formed. After this process is performed, a laser chip with a cavity length of about 300 μm is cut out, and a high reflectance dielectric multi-layered film is formed on each of the facets to complete a laser.

A characteristic temperature T₀, as an indicator of the temperature characteristics of the so prepared laser, is as high as 76K to 164K, while it is normally of the order of 45K for the InGaAsP-based semiconductor laser. Moreover, the maximum oscillation temperature is 100° C. or higher. Such satisfactory temperature characteristics may be attributed to the following facts: The conduction band discontinuity amount ΔEc of the InGaAsP-based material is as small as ΔEc=0.39ΔEg with respect to the entire bandgap difference ΔEg. With the InAlGaAs-based material, on the other hand, the conduction band discontinuity amount ΔEc is as large as ΔEc=0.72ΔEg. As a result, confinement of electrons takes place efficiently, and an overflow of electrons associated with a rise in the temperature is minimal. In addition, the analysis of a valence band structure shows that the InAlGaAs-based material has a greater differential gain than the InGaAsP-based material, as described in Journal of Applied Physics, Vol. 78, No. 6 (1995), 3925-3930. Thus, the InAlGaAs-based semiconductor laser has an ideal feature as a high speed direct modulation light source of 10 Gbps or more. Furthermore, the high speed modulation characteristics of a semiconductor laser are improved by applying compressive strain to the quantum well layer of the active layer. With the present material system, the element constituting the V group at the site of the active layer is only As. Thus, there is no formation of a strain-modified layer due to mixing of a plurality of group V elements at the interface as observed with the InGaAsP-based material. Since a satisfactory hetero interface free from a strain-modified layer can thus be formed, an ideal strongly strained quantum well structure can be easily achieved. Because of such advantages in manufacturing as well, the present material system is suitable for high speed modulation.

The above-described InAlGaAs-based laser involves minimal overflow of electrons as its inherent quality, and has a feature suitable for high speed modulation. However, a doping profile, as well as the structure of the quantum well, is important as a factor which determines the modulation speed. The following three examples are available as examples of the doping profile that greatly affects high speed modulation. The first example is to shorten the distance from the active layer to the doping front, thereby making it possible to shorten the transit time of carriers and improve modulation characteristics. The second example is to selectively dope only the barrier layer portion in the active layer into p type, thereby enabling the Fermi level to be controlled and the modulation characteristics to be improved (see Japanese Journal of Applied Physics, Vol. 29, No. 1 (1990), 81-87). The third example is a decrease in electric resistance. InAlAs has a great bandgap difference from InP in comparison with an InGaAsP system. Thus, band spikes occur in the valence band at the hetero interface between an InP cladding layer (in FIG. 10, p type InP spacer layer 21) and a layer (in FIG. 1, zinc-doped InAlGaAs compositionally graded layer 20) adjacent to a side in proximity to its active layer. Such spikes raise electric resistance, eventually increasing a CR time constant and deteriorating the modulation characteristics. As a means of suppressing such a resistance increase, it is effective to apply high concentration doping selectively to the hetero interface or the broad bandgap material side (here, InAlAs) in the vicinity of the hetero interface.

In the conventional example, zinc is usually used as the p type dopant, but zinc has a high diffusion coefficient, and moves during crystal growth. If such a dopant diffuses into the quantum well of the active layer, it becomes a non-radiative recombination center. Thus, a doping region is formed normally at least about 100 nm apart from the active layer, in anticipation of the movement of zinc. By so doing, the carrier transit time increases, and the modulation characteristics deteriorate, as stated earlier. Furthermore, diffusion increases in proportion to the square of the doping concentration. In the vicinity of the active layer, therefore, it is common practice to keep the doping concentration as low as 5×10¹⁷ cm⁻³. Essentially, it is desirable to apply an even higher concentration of doping to lower the electric resistance, thereby lowering the CR time constant concerned with the modulation speed. In this respect as well, zinc doping is disadvantageous.

In view of the foregoing facts, doping with zinc makes it impossible to control the doping profile precisely as in the aforementioned three examples. To deal with this problem, magnesium or beryllium may be used as a p type dopant with a small diffusion coefficient. However, magnesium has high reactivity and, when introduced, often deposits on the upstream side of piping. This produces a memory effect and, even after the introduction of magnesium is stopped, the deposit gradually arrives at the substrate and is taken up into it. This also makes precise control of the doping profile impossible. Since beryllium has extremely high toxicity which surpasses the toxicity of arsine, beryllium is scarcely used in MOVPE.

Carbon is also tried as a dopant with a low diffusion coefficient and low toxicity. Carbon doping presents a low diffusion coefficient, as shown in Journal of Crystal Growth, vol. 111 (1991), 274-279, and thus can achieve a steep doping profile with good controllability. Hence, carbon doping is often utilized for the AlGaAs system. With the InAlAs system, however, binding between indium and carbon is so weak that the problem of minimal uptake of carbon is posed. Actually, Journal of Crystal Growth, No. 221 (2000), 66-69, which describes carbon doping into InAlAs, reports that this doping requires a substrate temperature of 550° C., and a ratio of 20 between the total supply amount in mols of a group V material and the total supply amount in mols of arsenic hydride as a group III material (hereinafter referred to as the V/III ratio), namely, an extremely low temperature and an extremely low V/III ratio. Journal of Crystal Growth No. 108 (1991) 441-448, on the other hand, reports that a high temperature and a high V/III ratio are essential for achieving InAlAs having satisfactory optical characteristics. Based on these facts, a marked discrepancy is considered to exist between the conditions for growth of InAlAs for achieving a satisfactory optical quality and the conditions for growth of InAlAs for performing carbon doping. Carbon doping into InAlAs while retaining satisfactory optical characteristics has not been achieved yet. Nor has a semiconductor laser using carbon-doped InAlAs been realized, needless to say.

Because of the above-described problems, InAlAs-based materials have not achieved precisely controlled doping profiles required for high speed modulation, although they have distinctive features suitable for high speed modulation.

### SUMMARY OF THE INVENTION

The present invention has been accomplished in the light of the above-described problems with the prior art. It is an object of the present invention to provide a material comprising novel III-V compound semiconductor crystals having a carbon doping concentration controlled with high accuracy, especially, an InAlAs-based material or an InAlGaAs-based material having a more satisfactory quality. It is another object of the present invention to provide an electronic device excellent in current multiplication factor and high speed modulation characteristics, and a semiconductor laser excellent in light emission efficiency.

The inventors of the present invention diligently conducted studies, and succeeded in applying carbon doping in an InAlAs system and an InAlGaAs system, without impairing optical quality. They also succeeded in applying carbon doping to the vicinity of the active layer to shorten the carrier transit time; or in applying doping only to the barrier portion of the active layer to increase a modulation band; or in selectively applying high concentration carbon doping to an InAlAs portion in proximity to the interface between InAlGaAs and InP to lower electric resistance and improve CR time constant.

The III-V compound semiconductor crystals of the present invention are characterized in that they are III-V compound semiconductor crystals containing Al and In as main constituent elements of group III, and also containing a constituent element of group V, the carbon concentration in the compound semiconductor crystals is 1×10¹⁶ cm⁻³ or higher, and the oxygen concentration therein is 1×10¹⁸ cm⁻³ or lower and is not higher than the carbon concentration.

A method for producing the III-V compound semiconductor crystals of the present invention is characterized by supplying a group V material consisting essentially of a group V element-containing hydride and a group III material containing Al and In to a substrate to grow III-V compound semiconductor crystals on the substrate, while maintaining the temperature of the substrate at 650° C. or lower, setting the ratio of the amount in moles of supply of the group V material to the amount in moles of supply of the group III material at 25 or more, preferably 10 or more, and supplying a dopant gas containing carbon to the substrate.

The semiconductor device of the present invention is characterized by having a layered structure containing the above III-V compound semiconductor crystals. The semiconductor laser of the present invention is characterized by having a layered structure containing the above III-V compound semiconductor crystals. In the semiconductor laser of the present invention, the above III-V compound semiconductor crystals can be preferably used in at least some of separate confinement heterojunction layers (SCH layers), at least some of barriers of quantum well light emission layers, at least some of optical confinement layers (cladding layers), and/or at least some of graded refractive index layers.

### BRIEF DESCRIPTION OF DRAWINGS

FIG. 1 is a schematic view showing a carbon-doped InAlGaAs-based semiconductor laser structure.

FIG. 2 is a sectional view of an InAlGaAs-based semiconductor laser.

FIG. 3 is a view showing the relationship between a growth temperature and an oxygen concentration when 3.2 μmol/min of carbon tetrabromide is added during InAlAs growth.

FIG. 4 is a view showing the relationship between a growth temperature and a carbon concentration when 3.2 μmol/min of carbon tetrabromide is added during InAlAs growth.

FIG. 5 is a view showing the V/III ratio dependency of the oxygen concentration when 3.2 μmol/min of carbon tetrabromide is added during InAlAs growth.

FIG. 6 is a view showing the V/III ratio dependency of the carbon concentration when 3.2 μmol/min of carbon tetrabromide is added during InAlAs growth.

FIG. 7 is a view showing a multiple quantum well structure for photoluminescence measurement.

FIG. 8 shows photoluminescence spectra.

FIG. 9 is a view showing the characteristics of carbon doping into an InAlGaAs-based material.

FIG. 10 is a schematic view showing an InAlGaAs-based semiconductor laser structure as a conventional example.

FIG. 11 is a view showing injection current-light output characteristics and current-voltage characteristics in a device with a mesa width of 33 μm.

In the drawings, the reference numeral 1 denotes a carbon-doped InAlGaAs-based semiconductor laser substrate, 2 a carbon-doped barrier layer, 3 a carbon-doped upper graded refractive index (GRIN) layer, 4 a carbon-doped InAlAs layer, 5 a carbon-doped InAlGaAs compositionally graded layer, 10 an n type InP substrate, 11 an n type InP layer, 12 an n type InAlGaAs compositionally graded layer, 13 an n type InAlAs layer, 14 a lower graded refractive index (GRIN) layer, 15 a 5-period multiple quantum well layer, 16 a barrier layer, 17 an active layer, 18 an upper graded refractive index (GRIN) layer, 19 a zinc-doped InAlAs layer, 20 a zinc-doped InAlGaAs compositionally graded layer, 21 a p type InP spacer layer, 22 an InGaAsP etch stop layer, 23 a p type InP outer cladding layer, 24 a p type InGaAs cap layer, 25 a ridge, 26 a Si₃N₄ dielectric film, 27 a contact hole, 28 a p type electrode, and 29 an n type electrode.

### BEST MODE FOR CARRYING OUT THE INVENTION

The III-V compound semiconductor crystals and compounds of the present invention will be described in detail below. Herein, the range of numerical values expressed using “˜” refers to a range including the numerical values, described before and after “˜”, as a lower limit value and an upper limit value.

As hitherto reported, carbon-doped InAlAs crystals have oxygen slipped in and thus, when applied to a device, have not given sufficient optical characteristics under the influence of a non-radiative recombination center. The compound semiconductor crystals of the present invention have decreased in oxygen even when carbon-doped, and show satisfactory optical characteristics.

According to conventional reports, the InAlAs growth conditions, which enable carbon doping, are a low temperature and a low V/III ratio, and inevitably involve increases in oxygen impurities. Thus, in obtaining the III-V compound semiconductor crystals of the present invention, the V/III ratio is properly selected with respect to the growth temperature used, thereby making it possible to lower the oxygen concentration to 3×10¹⁷ cm⁻³ or less, and to achieve carbon doping in a concentration of 1×10¹⁸ cm⁻³ or more. Furthermore, a carbon material containing halogen, for example, carbon tetrabromide, is added as a dopant, whereby the oxygen concentration can be decreased further effectively.

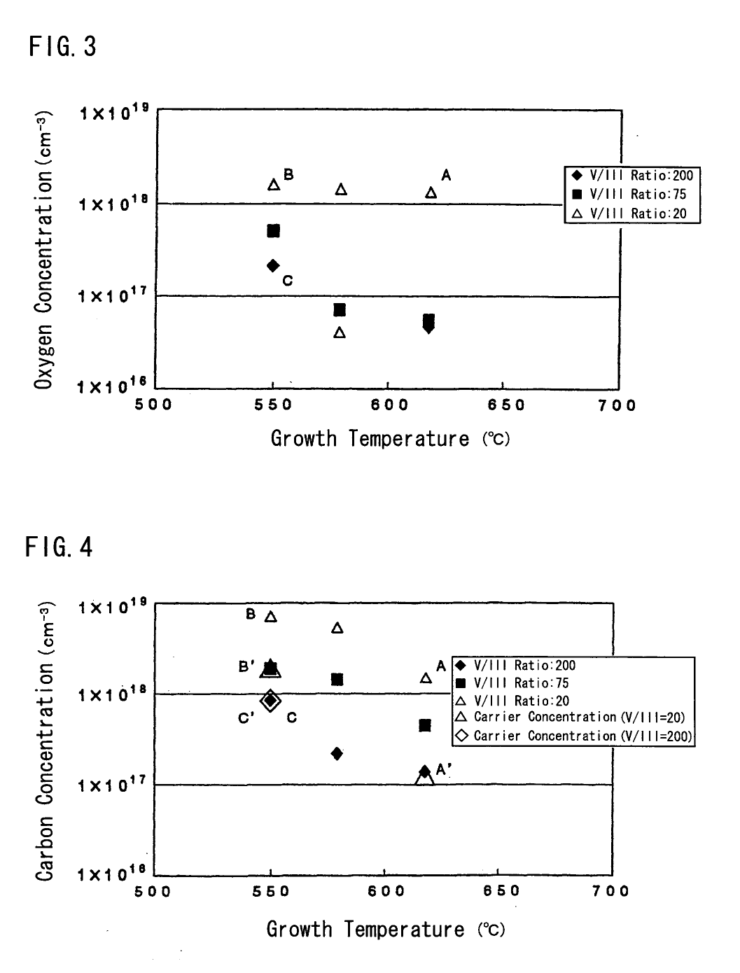

FIGS. 3 and 4 show the relationship between the growth temperature and the oxygen concentration or carbon concentration when InAlAs is grown, with carbon tetrabromide being added at a rate of 3.2 μmol/min. As shown in FIG. 3, when the V/III ratio is as low as 20, the oxygen concentration is as high as 1×10¹⁸ cm⁻³, regardless of whether the growth temperature is high (Point A) or low (Point B). When the V/III ratio is increased to 200, however, the oxygen concentration is as low as 2×10¹⁷ cm⁻³, even when the growth temperature is lowered to 550° C. (Point C). The carbon concentration under these conditions is about 1×10¹⁸ cm⁻³, a level permitting application to a device.

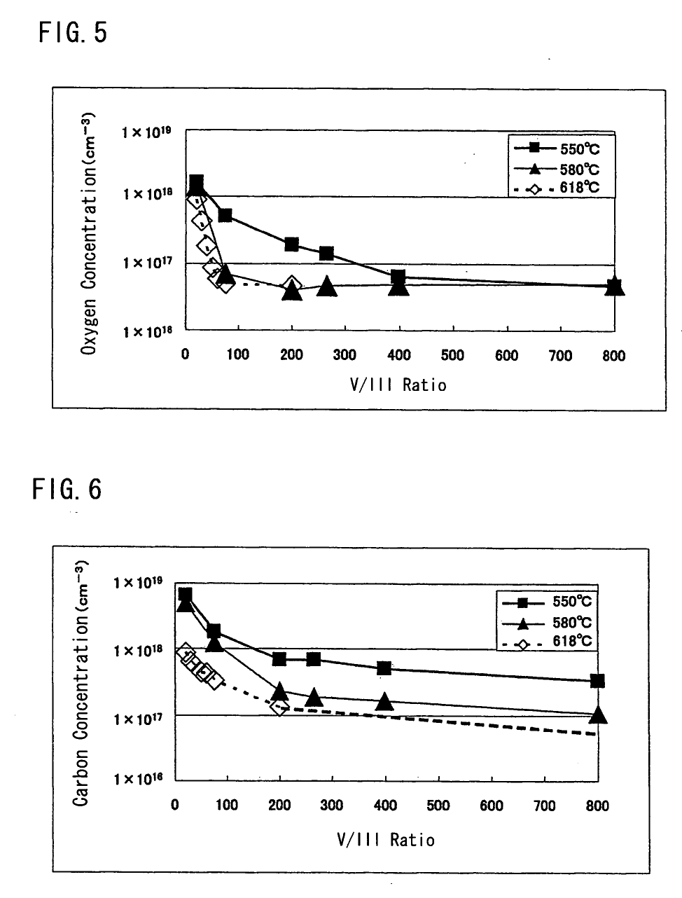

Next, similar data are used to show V/III ratio dependency, with the abscissa representing V/III and the ordinate representing the carbon concentration or oxygen concentration (FIG. 5, FIG. 6). At each temperature, the carbon concentration increases in reverse proportion to the V/III ratio in a low V/III ratio region. On the other hand, the oxygen concentration sharply increases on a low V/III ratio side, with a certain V/III ratio as a borderline, at each temperature. This behavior is more noticeable at high temperatures. At 618° C., for example, the oxygen concentration rises at a V/III ratio of 60 or less, whereas at 550° C. the oxygen concentration begins to increase at a V/III ratio of as high as about 400. The reason why the oxygen concentration increases at a certain V/III ratio or lower is presumed to be that at a low V/III ratio, at which As cannot cover the epitaxial surface any more, group V vacancies sharply increase, becoming oxygen traps. Besides, AsH₃ used here has a high decomposition efficiency at 618° C., as compared with 550° C. Thus, it covers the epitaxial surface and suppresses an increase in the oxygen concentration until a lower V/III ratio is reached.

Based on the above results, in order to achieve a high carbon concentration and a low oxygen concentration, it is desirable to select certain temperatures and, at these temperatures, use V/III ratios applied immediately before the oxygen concentration begins to rise. Such V/III ratios correspond to values in the vicinity of V/III ratios=60, 75 and 200 at temperatures of 618° C., 580° C. and 550° C., respectively. Concretely, at 650˜600° C., the V/III ratio is preferably 40˜500; at 600˜570° C., the V/III ratio is preferably 60˜500; and at 570˜540° C., the V/III ratio is preferably 150˜500.

The carrier concentrations determined by CV measurement at Points A, B and c are indicated by hollow marks (A′, B′, C′) in FIG. 4. The carrier concentrations in high oxygen concentration states (A, B) were much lower than the corresponding carbon concentrations. In a low oxygen concentration state (Point C), however, the carrier concentration agreed practically with the carbon concentration. These findings were ascribed to the facts that in the high oxygen concentration states A and B, p type carriers (holes) generated by the carbon added are cancelled out by oxygen serving as a donor, while when the oxygen concentration is decreased to 3×10¹⁷ cm⁻³ or less (Point C), the carbon added becomes operable as an acceptor efficiently. Such carrier compensation lowers the mobility of carriers, and thus exerts an undesirable influence on an electronic device. With the III-V compound semiconductor crystals of the present invention, the ratio of the carrier concentration to the carbon concentration in the crystals is normally 0.8 or higher, so that the crystals having such a ratio virtually equal to 1 are provided.

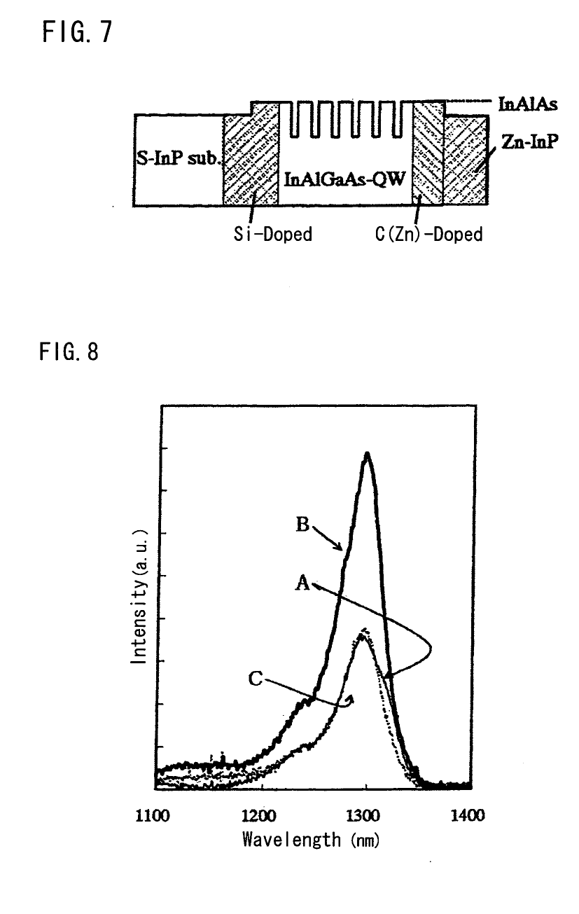

Next, the results of photoluminescence measurement will be described as an example of the optical characteristics evaluation of the III-V compound semiconductor crystals of the present invention. A multiple quantum well structure as shown in FIG. 7 was prepared, measured for carbon and oxygen concentrations by secondary ion mass spectroscopy, and measured for photoluminescence for the purpose of optical evaluation. The resulting emission spectra are shown in FIG. 8. Three samples were prepared in the case of carbon doping applied under oxygen-rich conditions (1×10¹⁸ cm⁻³) (Conditions A), in the case of carbon doping applied under oxygen-poor conditions (2×10¹⁷ cm⁻³) (Conditions B), and in the case of zinc doping (Conditions C), with the carrier concentration in InAlAs of the structure in FIG. 7 being set at (1×10¹⁸ cm⁻³). InAlAs by zinc doping was prepared under high temperature, high V/III ratio conditions, and thus had a low oxygen concentration. Under Conditions B with a decreased oxygen concentration, the photoluminescence spectrum had a narrow half width, and had a great intensity. Under Conditions A with a high oxygen concentration, the photoluminescence spectrum showed a wide half width, and had a low intensity. These results show that satisfactory optical characteristics are obtained by applying carbon doping at a decreased oxygen concentration. Under Conditions C involving zinc doping, the photoluminescence spectrum had a half width comparable to that in the oxygen-poor carbon-doped sample B, but its intensity was lower than that in the oxygen-poor carbon-doped sample B.

Based on the foregoing findings, it was found for the first time in the InAlAs layer that rendering the oxygen concentration lower than at least the carbon concentration is essential for obtaining satisfactory conduction characteristics and optical characteristics. Such concentrations can be controlled by the amounts of supply of a dopant containing carbon, such as carbon tetrabromide, and a source gas. However, in order to have the InAlAs layer function as a p type layer, a carbon concentration of the order of 1×10¹⁶ cm⁻³ is usually needed. Moreover, from the aspect of carrier compensation, it is necessary to render at least the oxygen concentration lower than the carbon concentration. Thus, the lower limit of the carbon concentration in the present invention is 1×10¹⁶ cm⁻³, but desirably, is 1×10¹⁷ cm⁻³, while the oxygen concentration is controlled to a value in a range lower than the carbon concentration. Of course, if the carbon concentration is further higher, the permissible upper limit of the oxygen concentration may be rendered further higher. However, the oxygen concentration is controlled to 1×10¹⁸ cm⁻³ or less. In consideration of a low-resistance effect, it is desired that the lower limit of the carbon concentration is 3×10¹⁷ cm⁻³, and the upper limit of the oxygen concentration is likewise 3×10¹⁷ cm⁻³. Most desirably, the carbon concentration is 5×10¹⁷ cm⁻³ or higher, and the oxygen concentration is 2×10¹⁷ cm⁻³ or lower. The oxygen concentration should be as low as possible, but the oxygen concentration lower than 1×10¹⁶ cm⁻³ poses difficulty in making accurate determination by the current method of analysis.

Besides, the upper limit of the carbon concentration is normally restricted by the limit of incorporation of carbon, but from the viewpoint of a device design, a value of the order of 1×10²⁰ cm⁻³ is considered to be appropriate as a measure of the upper limit. For example, carriers generated by doping constitute a factor for an optical absorption loss in a semiconductor laser. To minimize the loss, local high concentration doping may be performed only in a thin film of 5 nm or less. The doping concentration in this case may be so high as to reach 1×10²⁰ cm⁻³.

The oxygen concentration not higher than the carbon concentration may be achieved such that if the carbon concentration is high, the oxygen/carbon ratio is lower, and if the carbon concentration is low, the oxygen/carbon ratio is high to some degree.

In a carbon concentration range of 1×10¹⁶ cm⁻³ or higher, but lower than 5×10¹⁷ cm⁻³, the oxygen/carbon ratio is preferably 1 or less. In a carbon concentration range of 5×10¹⁷ cm⁻³˜2×10¹⁸ cm⁻³, the oxygen/carbon ratio is preferably 0.5 or less.

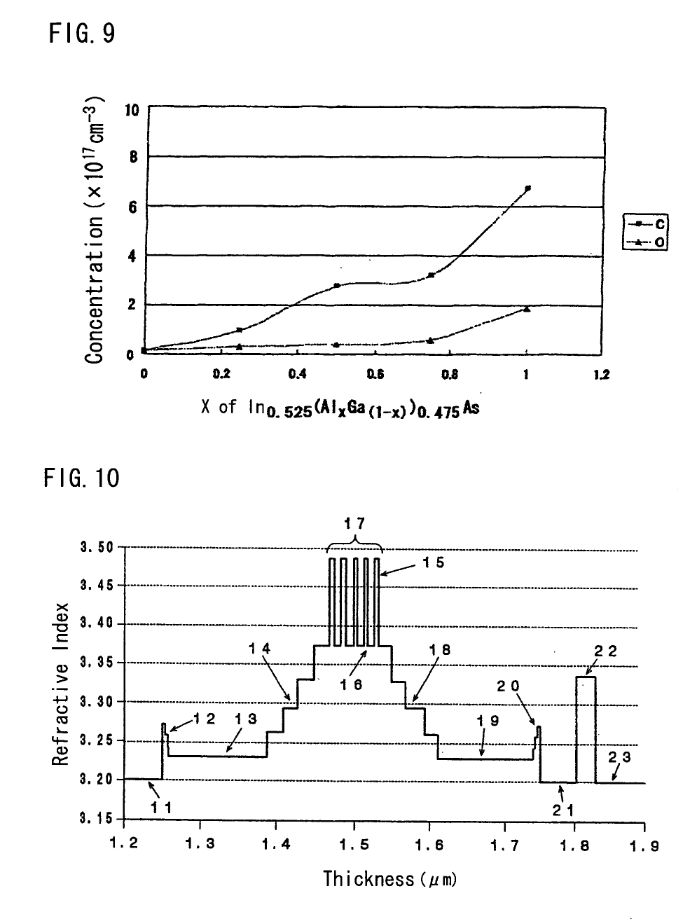

The results of carbon doping characteristics for quaternary composition InAlGaAs are shown in FIG. 9. An In_{0.525}(AlₓGa₁₋ₓ)_{0.475}As layer was formed on an InP substrate, with a constant amount of carbon tetrabromide being supplied to the substrate, and the carbon concentration and the oxygen concentration were investigated. The In_{0.525}(AlₓGa₁₋ₓ)_{0.475}As layer can be prepared, in a lattice matched state, on the InP substrate, and is used as a compositionally graded layer, or a barrier layer of an active layer portion, of a laser.

Based on FIG. 9, a carbon concentration of 3×10¹⁷ cm⁻¹³ or higher was obtained at an Al/Ga ratio (x) of 0.5 or more, and the oxygen concentration was as low as 2×10¹⁷ cm⁻³ or less over the entire region. The doping concentration can be rendered further higher by increasing the amount of carbon tetrabromide supplied, and the oxygen concentration canceling out p type carriers was low. In view of these facts, it has been found that the InAlGaAs layer with an Al/Ga ratio (x) of 0.5 or higher can be doped in a p type, and is not problematical in electrical conductivity characteristics or optical characteristics. That is, the present invention can be applied effectively to the In(AlₓGa₁₋ₓ)As layer with an Al/Ga ratio (x) of 0.5 or higher. As regards the ratio of In to Al+Ga, the above composition is a commensurate condition on the InP substrate, but actually, a strained composition is often used. In applying compressive strain, for example, the proportion of In is increased. In this case, the bandgap is narrowed in comparison with a no-strain state. As a corrective measure for this, Al in the Al:Ga ratio is increased. In such a case, the composition with a higher Al proportion leads to easier doping of carbon (as a p type). The reason is that an Al—C binding energy is greater than a Ga—C binding energy. However, a range in which the In proportion is 0.45˜0.80 and the ratio x between Al and Ga is 0.5 or more is desirable as a composition range which permits crystal growth on the InP substrate without lattice relaxation.

Hereinabove, the InAlGaAs system has been taken as an example. However, the present invention is applicable to systems containing other elements, such as P, N and Sb, in addition to In, Al, Ga and As. If the formulation of group V elements is different, any types of the group V elements may be used, because the ratio between the In—C binding energy and the Al—C binding energy is the same. Desirably, however, the proportion of As is usually at least 50% or more, preferably 90% or more, of all the group V elements, and the proportion of group V elements other than As is less than 50% of all the group V elements. Regarding group III elements such as In, Al and Ga, the present invention can be applied to a material system containing In and Al as main constituent elements in all group III elements. In and Al, or In, Al and Ga, usually, account for at least 50% or more, preferably 90% or more, of all group III elements. The ratio of Al to Ga is 1:1 or higher, and a higher proportion of Al is desirable. In connection with the method of growth, methods using organometallic compounds include chemical beam epitaxy (CBE) and metal organic molecular beam epitaxy (MOMBE), but metal organic vapor phase epitaxy (MOVPE) is the most desirable method.

In regard to the range of the carbon doping concentration, if an optical absorption loss is to be further decreased, the doping concentration may be further lowered, although electric resistance is somewhat increased. If emphasis is placed on a reduction in electric resistance, an increase in the doping concentration is permissible, although the optical absorption loss is increased. In a narrow range, even a very high concentration of doping results in a small optical absorption loss, so that the upper limit of the doping concentration may be high. Based on these requirements, the range of the doping concentration is determined and, numerically, is of the order of 1×10¹⁷ cm⁻³˜1×10²⁰ cm⁻³. The range of the oxygen concentration needs to be lower than the carbon concentration and, when the carbon concentration is 5×10¹⁷ cm⁻³, is desirably 2×10¹⁷ cm⁻³ or less.

In preparing a light-emitting device such as a semiconductor laser, the carbon doping concentration is preferably 5×10¹⁷ cm⁻³˜2×10¹⁸ cm⁻³ in the InAlGaAs barrier layer of the active layer, is preferably 5×10¹⁷ cm⁻³˜2×10¹⁸ cm⁻³ in the graded refractive index (GRIN) layer, is preferably 5×10¹⁷ cm⁻³˜2×10¹⁸ cm⁻³ in the SCH layer of InAlAs, and is preferably 5×10¹⁷ cm⁻³˜2×10¹⁹ cm⁻³ in the InAlGaAs compositionally graded layer. The oxygen concentration is preferably 2×10¹⁷ cm⁻³ or less in all layers.

The growth temperature is not restricted, but if it is set at 650° C. or lower, efficient incorporation of carbon can be performed. Therefore, the upper limit of the growth temperature is preferably 650° C. or lower, more preferably 620° C. or lower, even more preferably 600° C. or lower, and most preferably 585° C. or lower. The lower limit of the growth temperature is preferably 450° C. or higher, more preferably 500° C. or higher, and most preferably 540° C. or higher, from the viewpoint of crystallinity and the viewpoint of decomposition of the starting material. The ratio between the total supply amount in moles of the group V materials and the total supply amount in moles of the group III materials (i.e., V/III ratio) may be of the order of 25, if the growth temperature or the growth rate is adjusted. Even in this case, the effects of the present invention are obtained. Thus, the lower limit of the V/III ratio is preferably 25 or more, more preferably 50 or more, and most preferably 150 or more. The upper limit of the V/III ratio is determined mainly by the rate-determining aspect of the apparatus used. To raise the V/III ratio, it is often necessary to decrease the group III material, because an increase in the group V material is not enough. This necessity results in a decreased growth rate, eventually increasing the uptake of oxygen in the atmosphere. From this viewpoint, the upper limit of the V/III ratio is preferably 500 or lower, more preferably 300 or lower, and even more preferably 250 or lower. This applies in a case where a group V material, such as an arsenic-containing hydride, for example, arsine, is used as a group V gas.

If the growth temperature is 550° C. or lower, and a halogen material is not added, uptake of oxygen increases over the entire range of the V/III ratio. Thus, the addition of a halogen material produces the effect of decreasing the oxygen content. Especially under the conditions involving the growth temperature of 580° C. or lower and the V/III ratio of 100 or lower, the effects of the present invention are marked. In a region in which the growth temperature exceeds 620° C., the uptake of oxygen increases at the V/III ratio of 100 or lower. Thus, the addition of a halogen material produces the effect of decreasing the oxygen content. Further, the effects of the present invention are conspicuous under the conditions involving the growth temperature of 650° C. or lower and the V/III ratio of 50 or lower.

If an organic compound containing arsenic, such as tertiary-butylarsine (TBA) or trimethylarsenic (TMAs), is used as the group V material, the upper limit of the V/III ratio is usually 250 or lower, preferably 100 or lower, even more preferably 50 or lower, and particularly preferably 20 or lower, from the rate-determining aspect of the apparatus. The lower limit of the V/III ratio is preferably 2 or higher, and more preferably 5 or higher.

Hereinabove, carbon tetrabromide has been used as the carbon dopant. However, the use, as the carbon dopant, of various materials containing halogens (hereinafter generally referred to as halogen materials), such as chlorine tetrabromide, hydrogen chloride, tertiary-butyl chloride, monochloromethane, and bisdimethylaminophosphine chloride, is preferred, because this use is found to have a tendency toward avoiding the uptake of oxygen. If, in the current situation, consideration is given to purity, burden on the environment, and controllability, the most desirable material may be carbon tetrabromide. If a halogen material, which does not serve as a carbon dopant, is used as a halogen-containing gas, uptake of carbon does not occur, but the effect of decreasing oxygen in the undoped layer can be expected.

In regard to the amount of the halogen material added, halogen materials other than carbon tetrabromide may be added in amounts comparable to the amount of carbon tetrabromide added, because they obtain the same effect, if they produce halogen atoms upon thermal decomposition, no matter what halogen materials they are. However, oxygen is mainly bound to a group III element, so that it would be reasonable to think of the amount of addition of halogen based on its ratio to the group III element. According to this theory, the amount of supply in moles of the halogen material is desirably about 2%˜15% of the amount of supply in moles of the group III element, based on the amount of supply in moles of the group III element (75 μmol/min) used in FIG. 2. This lower limit is a necessary amount to reduce the oxygen concentration at least by half, and the upper limit can be estimated from the point of view of suppressing changes in mixed crystal compositional proportions.

The compound semiconductor crystals of the present invention can be put to various uses. For example, a compound semiconductor device containing the compound semiconductor crystals of the present invention in a layered structure can be produced. Concretely, a semiconductor layer, which uses the compound of the present invention as a p-side separate confinement heterojunction layer (SCH layer), as the barrier of a quantum well light emission layer, or as a p-side optical confinement layer (cladding layer), can be produced. As the structure of such a semiconductor-laser, it is possible to employ a hitherto known structure selected, as desired, according to the purpose to be attained. For example, the structures described in the Example to be offered later can be quoted as examples.

The magnitude of the refractive indexes of the respective layers constituting the semiconductor laser is as follows: Quantum well layer of the active layer>barrier layer of the active layer>separate confinement heterojunction layer (SCH layer) and cladding layer. The n type and p type InAlAs-SCH layers are designed to carry out optical confinement, increasing the efficiency of lasing. Thus, these layers are formed adjacent to and outwardly of the active layer. The composition, in the case of an InAlGaAs system, is the same as in the composition range of the barrier layer to be described below. The lower graded refractive index layer and the upper graded refractive index layer (GRIN layers) are intended for decreasing band spikes, and thus their composition ranges are the same. However, the GRIN layer also contributes to optical confinement of the surroundings of the active layer. Thus, its thickness is set in consideration of this confinement, and the lower limit of the thickness of one side is preferably 10 nm or more, while the upper limit is preferably 200 nm or less. The active layer is composed of the multiple quantum well layer and the barrier layer, and is aimed at varying the state density function by a quantum effect, thereby increasing a gain obtained when carriers are converted into light. Thus, its composition and thickness need to be enough to produce this effect. The quantum well layer needs to have a bandgap set such that the desired light emission wavelength (shorter by about 20 nm than the lasing wavelength) is obtained. Moreover, its laser characteristics are improved by applying compressive strain to such a degree that lattice relaxation does not occur. These limitations determine its composition. If a laser having an oscillation wavelength of 1.25 μm˜1.65 μm is to be produced, the proportion of In is preferably 0.45˜0.80. The ratio x of Al to Ga is preferably 0˜0.5. The composition of the barrier layer needs to have a wider bandgap than the quantum well layer so that a quantum effect will appear. Its In proportion is preferably 0.45˜0.80. Its Al/Ga ratio x is preferably 0.5˜1.

The compositionally graded layer is intended to decrease band spikes between the cladding layer (InP layer) and the optical separate confinement layer (InAlAs layer) and lower electric resistance. If the compositionally graded layer comprises InAlGaAs, its composition is set such that its bandgap is intermediate between those of InP and InAlAs, and its location is set to be between InP and an active region including SCH. The upper limit of the thickness of the compositionally graded layer is preferably 50 nm or less, and more preferably 20 nm or less. On the other hand, the lower limit of its thickness is preferably 5 nm or more, and more preferably 10 nm or more.

### EXAMPLE

The characteristics of the present invention will be described further concretely by reference to an Example. The materials, amounts used, proportions, contents of processing, and procedures for processing shown in the following Example can be changed, as appropriate, unless such changes deviate from the purport of the present invention. Hence, the scope of the present invention should not be interpreted as restricted by concrete examples to be shown below.

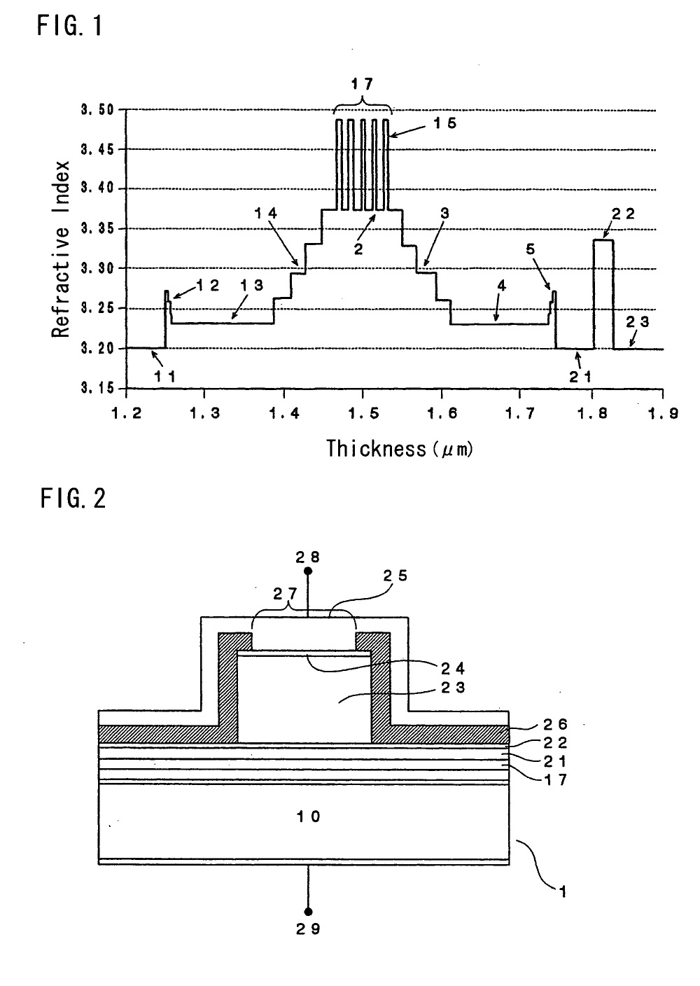

In the present Example, a device having a structure shown in FIG. 1 and FIG. 2 was produced. The drawings attached hereto are partly changed in dimensions for easy grasping of the structure. However, the actual dimensions are as described in the following sentences.

As shown in FIG. 1, an n type InP layer 11, an n type InAlGaAs compositionally graded layer 12, an n type InAlAs-SCH layer 13, a lower graded refractive index (GRIN) layer 14, an active layer 17 consisting of 6 nm wide 5-period multiple quantum well layers 15 (AlGaInAs) and 10 nm wide carbon-doped barrier layers 2 (InAlGaAs), a carbon-doped upper graded refractive index (GRIN) layer 3, a carbon-doped InAlAs-SCH layer 4, a carbon-doped InAlGaAs compositionally graded layer 5, a p type InP spacer layer 21, an InGaAsP etch stop layer 22, a p type InP outer cladding layer 23, and a p type InGaAs cap layer 24 were sequentially stacked on an n type InP substrate 10 with the use of MOVPE.

The doping concentrations were 1×10¹⁸ cm⁻³ for all of the InAlGaAs barrier layers 2 of the active layer, the carbon-doped upper graded refractive index (GRIN) layer 3, and the carbon-doped InAlAs layer, and 5×10⁸ cm⁻³ for the carbon-doped InAlGaAs compositionally graded layer 5. The oxygen concentration was 2×10¹⁷ cm⁻³ or lower for all layers.

After a carbon-doped InAlGaAs-based semiconductor laser substrate 1 as described above was formed, a process as shown below was performed to prepare an InAlGaAs-based semiconductor laser as illustrated in FIG. 2. A photoresist mask with stripes on the order of 5 μm in width and 300 μm in pitch was formed on the stacked structure. Wet etching was carried out with the use of this mask to form ridges 25. During the wet etching, an aqueous mixed solution of phosphoric acid and hydrogen peroxide was used on the p type InGaAs cap layer 24, and a diluted aqueous solution of hydrochloric acid was used on the p type InP outer cladding layer 23, whereby etching was stopped at the InGaAsP etch stop layer 22 with good controllability. Then, the photoresist was stripped off, and an insulating film, such as a Si₃N₄ dielectric film 26, was formed on the entire surface. Further, contact holes 27 were selectively perforated in stripes on the top portions of mesas of the Si₃N₄ dielectric film 26, and a p type electrode 28 was formed. The substrate was polished to a thickness as thin as 100 μm, and an n type electrode 29 was formed. After this process was performed, a laser chip with a cavity length of about 300 μm was cut out, and a high reflectance dielectric multi-layered film was formed on each of the facets to complete a laser.

The spacing from the doping front to the quantum well in the present device was only the width (about 10 nm) of the barrier layer of the active layer, and a delay in the modulation speed by the carrier transit time was shortened practically negligibly. By applying carbon doping to the barrier layer, moreover, the carrier lifetime decreased to 1/10 of that in undoping, as indicated in the aforementioned Japanese Journal of Applied Physics, Vol. 29, No. 1 (1990), 81-87. Furthermore, high concentration doping was selectively applied to the InAlGaAs compositionally graded layer undergoing band spikes, whereby electric resistance decreased from 20 Ω to 7 Ω. Because of the above-mentioned improvements on the device structure, the modulation bandwidth (relaxation oscillation frequency fr) at 85° C. in the present device became 12 GHz, which was a 1.5-fold increase over a zinc-doped device (8 GHz).

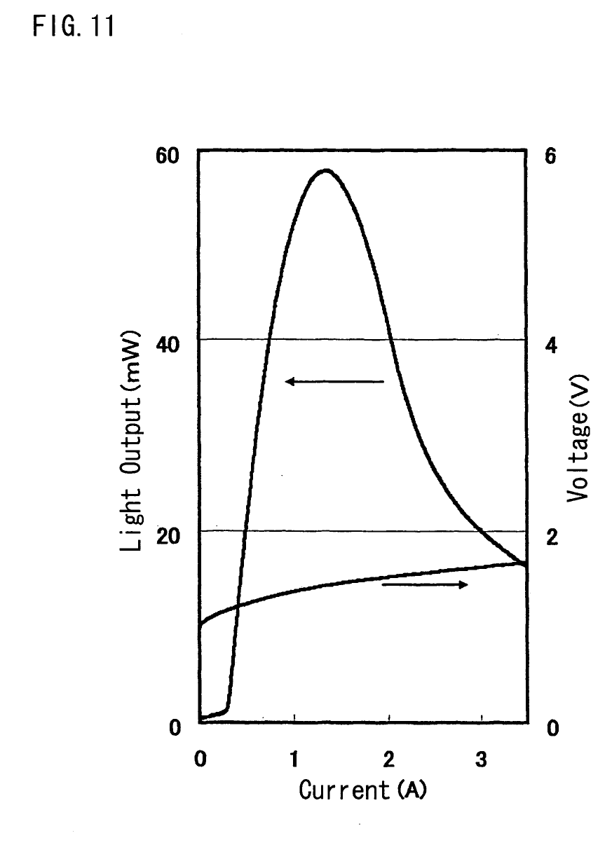

In addition, etching was performed using a 33 μm wide photoresist mask in preparing the ridges 25 during the process of device production. Further, a cavity length was set at 500 μm, and a device was prepared, but without facet coating. This device was examined for current-voltage characteristics and current-light output characteristics. The results are shown in FIG. 11. In this study, a current of up to 3.5 A was applied as an eddy current test. The differential electric resistance of the device was as low as 1.2 Ω, which was comparable to that of a conventional material-based InGaAsP-LD. The threshold current density of the device was 1.6 A/cm², which was comparable to the documented value of a similar InAlGaAs-based Zn-doped LD (IEEE Journal on Selected Topics in Quantum Electronics, vol. 7, No. 2 (2001), 340-349). These findings mean that the device doped with carbon in accordance with the present invention is comparable to the conventional Zn-doped device in the optical characteristics at room temperature, and is low in electric resistance, showing improvements. When the electric resistance is low, an improvement in the optical characteristics at a high temperature can be expected. Worthy of special note is that although the device of the present invention was made of a material system containing highly reactive Al, it showed no COD (catastrophic optical damage), but showed thermal saturation characteristics, even when a high current of 3.5 A was passed. Nor was any change observed between the device characteristics before and after such an eddy current test. These results show that carbon doped in the vicinity of the active layer did not diffuse into the active layer during and after the eddy current test and, even when diffusing therein, did not adversely affect light emission characteristics. This is proof of superiority over zinc doping. A report says that when oxygen is introduced into an active layer, a non-radiative recombination center is formed, resulting in the deterioration of optical emission characteristics (Applied Physics Letters, vol. 40 (1982) 614, and Journal of Applied Physics 73 (1993), 4004). The results of the present study showed that no deterioration of light emission characteristics was noted, because of the effect of lowering the oxygen concentration.

An improvement in device characteristics can be achieved by using a carbon-doped InAl(Ga)As layer in the layered structure of a semiconductor laser. The InAlAs layer is considered to be promising in realizing a high speed, high output compound electronic device, owing to the characteristics of its band structure. Such compound electronic devices include a heterojunction bipolar transistor (HBT), a field effect transistor (FET), and a high electron mobility transistor (HEMT). In this case as well, the use of carbon, rather than zinc, as a p type dopant makes it possible to control the doping profile accurately. Furthermore, a decrease in oxygen permits doping with a minimal carrier compensation and high hole mobility. Hence, an overall improvement in device characteristics can be achieved.

The present disclosure relates to the subject matter contained in PCT/JP03/12007 filed on Sep. 19, 2003, Japanese Patent Application No. 274905/2002 filed on Sep. 20, 2002, Japanese Patent Application No. 274906/2002 filed on Sep. 20, 2002, Japanese Patent Application No. 274907/2002 filed on Sep. 20, 2002, Japanese Patent Application No. 130264/2003 filed on May 8, 2003 and Japanese Patent Application No. 130265/2003 filed on May 8, 2003, which are expressly incorporated herein by reference in their entirety.

The foregoing description of preferred embodiments of the invention has been presented for purposes of illustration and description, and is not intended to be exhaustive or to limit the invention to the precise form disclosed. The description was selected to best explain the principles of the invention and their practical application to enable others skilled in the art to best utilize the invention in various embodiments and various modifications as are suited to the particular use contemplated. It is intended that the scope of the invention not be limited by the specification, but be defined claims set forth below.

1. A III-V Compound semiconductor crystal containing Al and In as main constituent elements of group III, and also containing a constituent element of group V, wherein a carbon concentration in said compound semiconductor crystals is 1×10¹⁶ cm⁻³ or higher, and an oxygen concentration therein is 1×10¹⁸ cm⁻³ or lower and is not higher than said carbon concentration.

2. The III-V compound semiconductor crystals as claimed in claim 1, further containing Ga as a main constituent element of group III.

3. The III-V compound semiconductor crystals as claimed in claim 1, containing As as a main constituent element of group V.

4. The III-V compound semiconductor crystals as claimed in claim 1, wherein a ratio of a carrier concentration to the carbon concentration in said crystals is 0.8 or higher.

5. A semiconductor device having a layered structure containing the III-V compound semiconductor crystals of claim 1.

6. A semiconductor laser having a layered structure containing the III-V compound semiconductor crystals of claim 1.

7. A semiconductor laser having separate confinement heterojunction layers wherein the III-V compound semiconductor crystals of claim 1 are used in at least some of the separate confinement heterojunction layers.

8. A semiconductor laser having barriers of quantum well light emission layers wherein the III-V compound semiconductor crystals of claim 1 are used in at least some of the barriers of quantum well light emission layers.

9. A semiconductor laser having optical confinement layers wherein the III-V compound semiconductor crystals of claim 1 are used in at least some of the optical confinement layers.

10. A semiconductor laser having graded refractive index layers wherein the III-V compound semiconductor crystals of claim 1 are used in at least some of the graded refractive index layers.

11. A method for producing the III-V compound semiconductor crystals of claim 1, comprising supplying a group V material consisting essentially of a group V element-containing hydride, and a group III material containing Al and In to a substrate to grow III-V compound semiconductor crystals on the substrate, while maintaining a temperature of the substrate at 650° C. or lower, setting a ratio of an amount in moles of supply of the group V material to an amount in moles of supply of the group III material at 25 or higher, and supplying a dopant gas containing carbon to the substrate.

12. A method for producing the III-V compound semiconductor crystals of claim 1, comprising supplying a group V material consisting essentially of a group V element-containing hydride, and a group III material containing Al and In to a substrate to grow III-V compound semiconductor crystals on the substrate, while maintaining a temperature of the substrate at 650° C. or lower, setting a ratio of an amount in moles of supply of the group V material to an amount in moles of supply of the group III material at 10 or higher, and supplying a dopant gas containing carbon to the substrate.

13. The method for producing the III-V compound semiconductor crystals as claimed in claim 11, wherein said group V material is an organometallic compound.

14. The method for producing the III-V compound semiconductor crystals as claimed in claim 11, wherein the temperature of the substrate is maintained at 620° C. or lower.

15. The method for producing the III-V compound semiconductor crystals as claimed in claim 11, wherein the temperature of the substrate is maintained at 450° C. or higher.

16. The method for producing the III-V compound semiconductor crystals as claimed in claim 11, wherein the group III material further contains Ga.

17. The method for producing the III-V compound semiconductor crystals as claimed in claim 11, wherein that the group V material contains As.

18. A method for producing the III-V compound semiconductor crystals of claim 1, comprising supplying a group V material, and a group III material containing Al and In to a substrate to grow III-V compound semiconductor crystals on the substrate, while maintaining a temperature of the substrate at 650° C. or lower, and supplying a gas containing a halogen to the substrate.

19. The method for producing the III-V compound semiconductor crystals as claimed in claim 18, comprising supplying the gas containing the halogen to the substrate in such an amount that [an amount in moles of a halogen material supplied]/[an amount in moles of the group III material supplied] is 2˜15%.

20. The method for producing the III-V compound semiconductor crystals as claimed in claim 18, comprising supplying carbon tetrabromide as the gas containing the halogen.

21. The method for producing the III-V compound semiconductor crystals as claimed in claim 18, wherein the group V material contains As.

22. The method for producing the III-V compound semiconductor crystals as claimed in claim 21, wherein the group V material consists essentially of a hydride containing As, and a ratio of an amount in moles of supply of a group V element to an amount in moles of supply of a group III element is 500 or lower.

23. The method for producing the III-V compound semiconductor crystals as claimed in claim 21, wherein the group V material consists essentially of an organic compound containing As, and a ratio of an amount in moles of supply of a group V element to an amount in moles of supply of a group III element is 50 or lower.
